(19) United States
(12) Patent Application Publication
(10) Pub. No.: US 2011/0234062 A1
(43) Pub. Date: Sep. 29, 2011

(54) ELECTRONIC DEVICE AND LOCKING MECHANISM THEREOF

(75) Inventors: KUN-CHIH HSIEH, Tu-Cheng (TW); JIAN-QIANG ZHAO, Shenzhen City (CN); JIN-SHENG HUANG, Shenzhen City (CN)

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/908,844

(22) Filed: Oct. 20, 2010

(30) Foreign Application Priority Data
Mar. 26, 2010 (CN) 201010133481.5

(51) Int. Cl. H05K 5/03; E05C 19/16; E05C 19/10

(52) U.S. Cl. 312/223.1; 292/251.5

(57) ABSTRACT

An electronic device includes an upper cover, bottom cover and locking mechanism to connect the upper cover to the bottom cover. The locking mechanism includes a plurality of protrusions formed on an inner surface of the bottom cover, elastic members and a blade. The blade is slidably mounted on the upper cover and capable of being attracted by an external magnetic member. The blade is formed with hooks. Each protrusion defines a notch. The hooks are urged by the elastic members to be received in the notch and connect the upper cover to the bottom cover. The hooks are capable of moving out of the notches by the force of the external magnetic member, allowing the upper cover to detach from the bottom cover. A locking mechanism configured for connecting an upper cover to a bottom cover is also provided.

### BACKGROUND

1. Technical Field

The present disclosure relates to electronic devices, especially to an electronic device with a locking mechanism.

2. Description of Related Art

Generally, a cover and a main body of an electronic device can be connected together by a locking mechanism such as hooks and coupling holes formed on the cover and the main body respectively. Although the conventional locking mechanism satisfy basic requirements, a new locking mechanism for an electronic device is still needed.

### BRIEF DESCRIPTION OF THE DRAWINGS

Many aspects of the embodiments can be better understood with reference to the accompanying drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device according to an exemplary embodiment.

FIG. 2 is an exploded view of the electronic device with the upper cover and bottom cover partially cut away.

FIG. 3 is similar to FIG. 2, but viewed from a different aspect.

FIG. 4 is an isometric view of a blade with elastic members viewed from the rear.

FIG. 5 is a partial, assembled front view of FIG. 1, with the bottom cover omitted.

FIG. 6 is partial, cross-sectional view of the electronic device in FIG. 1, taken along line VI-VI.

FIG. 7 is a cutaway view showing a hook out of a notch in FIG. 5.

### DETAILED DESCRIPTION

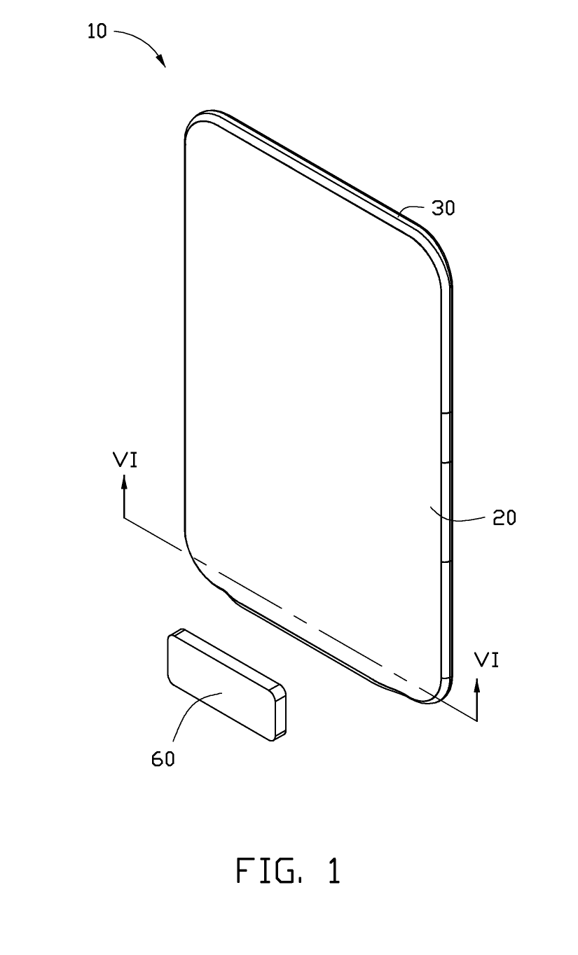

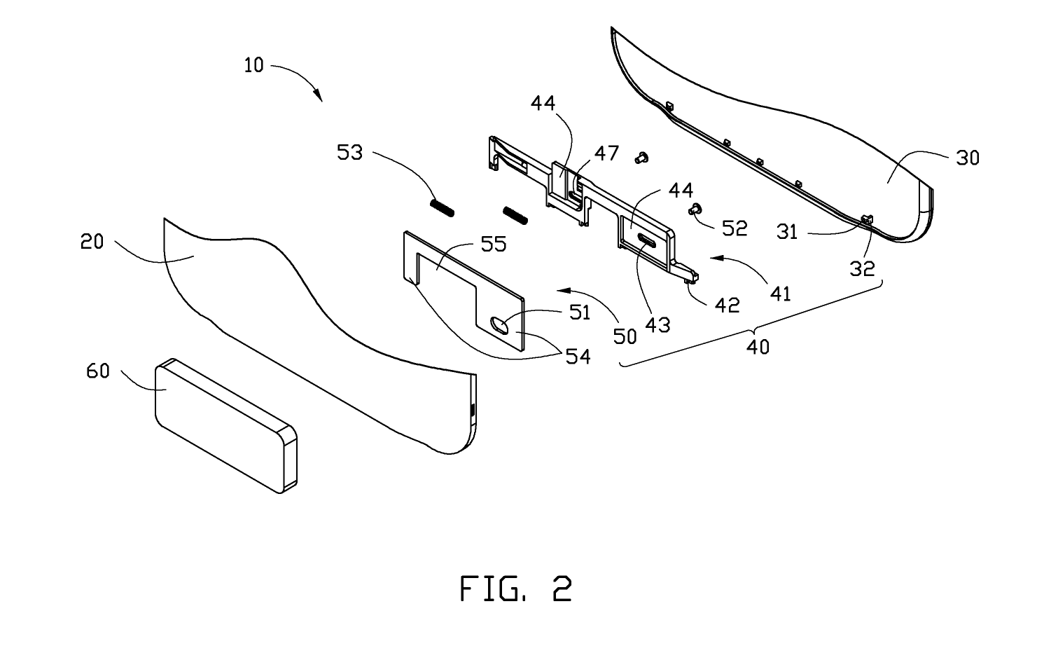

Referring to FIGS. 1 and 2, an electronic device 10 includes an upper cover 20, a bottom cover 30 and a locking mechanism 40 for connecting the bottom cover 30 to the upper cover 20.

The locking mechanism 40 includes a blade 41 and a magnetic member 50. The blade 41 defines a number of L-shaped hooks 42, a first slide slot 43, a second slide slot 47, and two recesses 44. The hooks 42 are vertically protruded from one side of the blade 41. The first slide slot 43 and the second slide slot 47 are substantially perpendicular to the hook 42. The first slide slot 43 communicates with one of the recesses 44, and the second slide slot 47 is adjacent to the other of the recesses 44. The magnetic member 50 includes two ends 54. An opening 55 is defined between the two ends 54. The two ends 54 are received in the two recesses 44 correspondingly. The blade 41 is affixed on the magnetic member 50 by the attractive magnetic force of the magnetic member 50. The magnetic member 50 defines a slide groove 51 corresponding to the first slide slot 43.

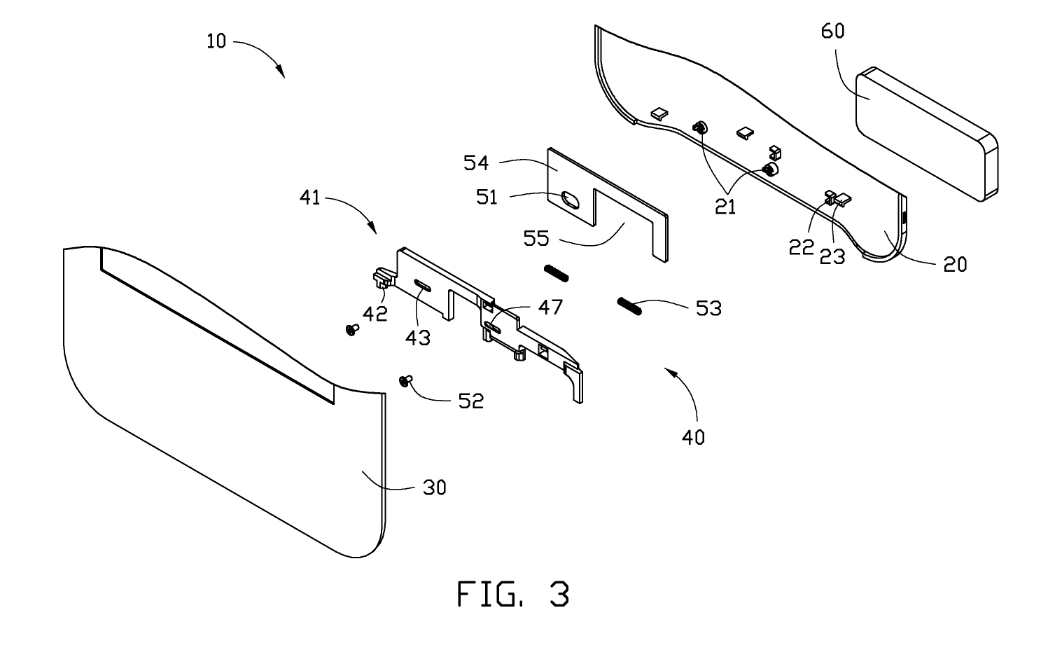

Referring to FIG. 3, the upper cover 20 defines two screw holes 21, two U-shaped blocks 22 and three L-shaped restriction blocks 23. A bolt 52 passes through the first slide slot 43 and the second slide slot 51 and is screwed into one of the screw holes 21. Another bolt 52 passes through the second slide slot 47 and the opening 55 and is screwed into the other of the screw hole 21. The blade 41 is thus mounted on the upper cover 20 and positioned below the restriction blocks 23. The blade 41 can move along the extending direction of the slide slots 43 and 51.

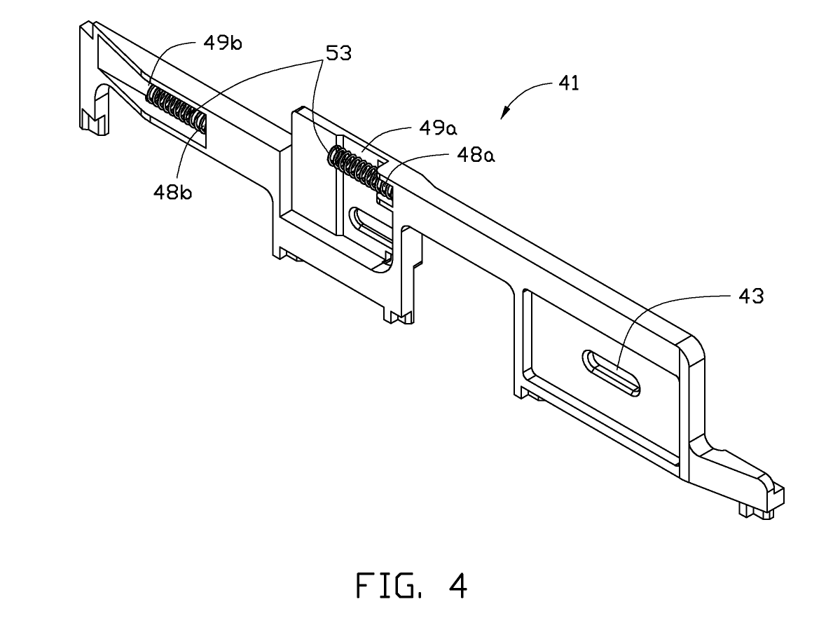

Referring also to FIG. 4, the locking mechanism 40 further includes two elastic members 53. The blade 41 further defines two indentations 49a and 49b. The indentation 49a is formed in the recess 44 communicating with the slide slot 47, and the indentation 49b in an end of the blade 41 far away from the first slide slot 43. Two spindles 48a and 48b and are extended from a flange of the indentations 49a and 49b correspondingly. The extending directions of the spindles 48a and 48b are parallel to the slots 43 and 47. The elastic members 53 are sleeved on the two spindles 48a, 48b correspondingly. The free end of each of the two elastic members 53 are received in one of the U-shaped blocks 22 correspondingly.

Referring again to FIG. 2, a number of protrusions 32 are defined on an inner surface of the bottom cover 30. Each protrusion 32 defines an L-shaped notch 31 configured for receiving the corresponding L-shaped hook 42 to connect the upper cover 20 to the bottom cover 30.

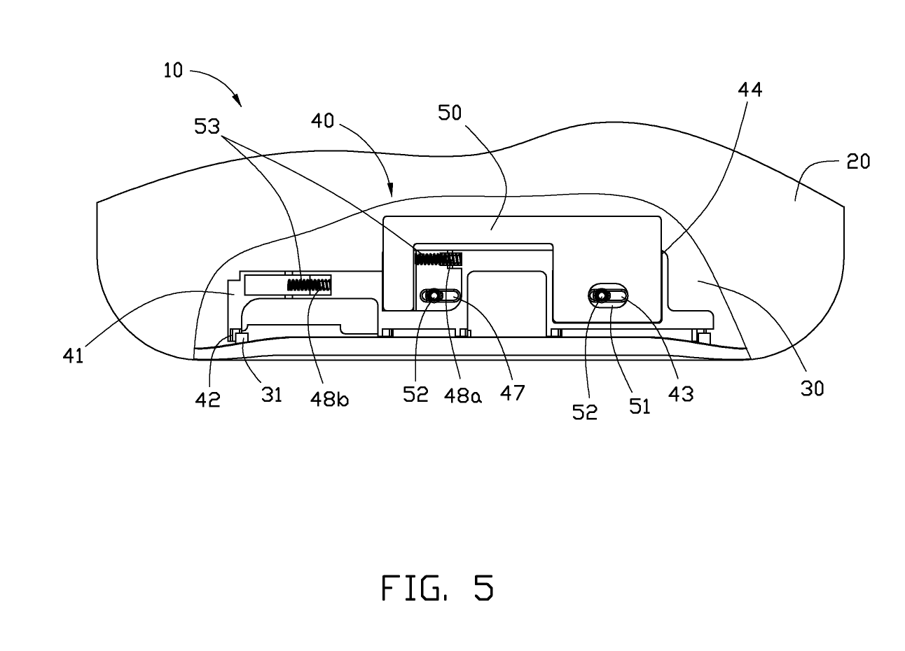

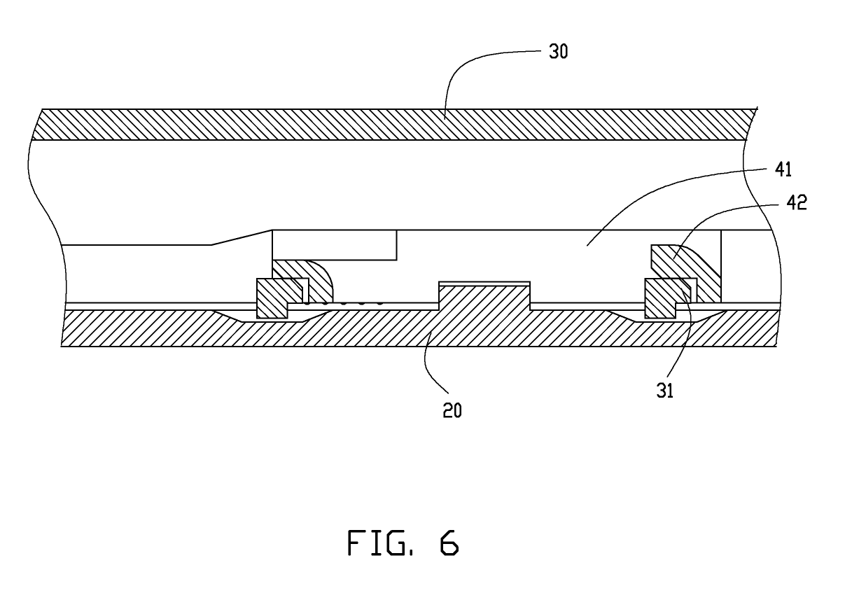

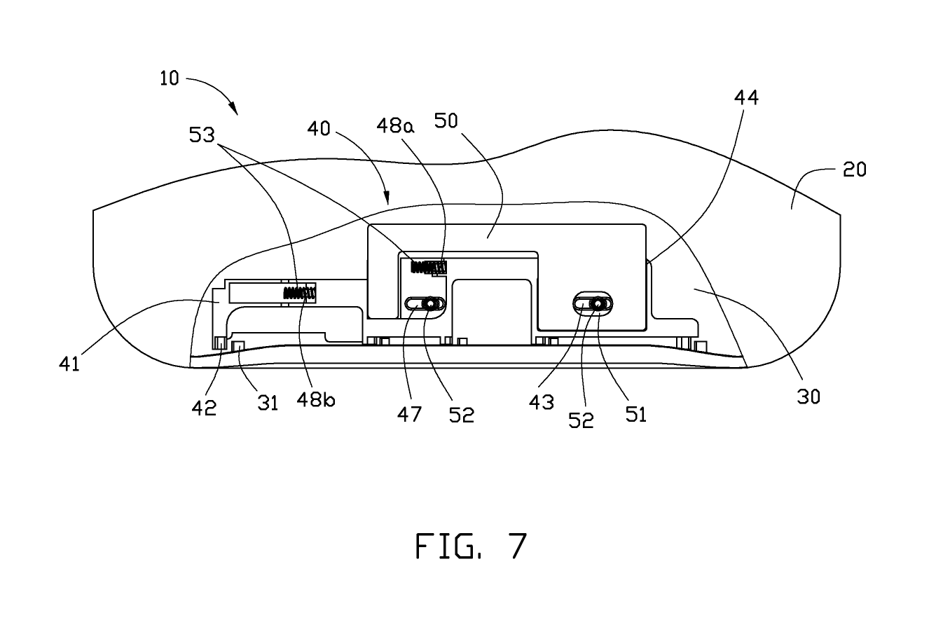

Referring to FIGS. 5 and 6, when the upper cover 20 is folded to the bottom cover 30, the hooks 42 are received in the corresponding notches 31 and the two bolts 52 are respectively disposed in the first slide slot 43 and the second slide slot 47 adjacent to the spindle 48b. Referring also to FIGS. 1 and 7, when detaching the upper cover 20 from the bottom cover 30, an external magnet 60 is employed to move across the outer surface of the upper cover 20 to attract the magnet 60 and force the magnet 60 to move. With the magnetic member 50, the magnetic force between the blade 41 and the magnet 60 is strengthened. As the magnet 60 moves, the blade 41 is attracted to slide along the extending direction of the first slide slot 43 and the second slide slot 47. The hooks 42 can then move out of the notches 31, allowing the upper cover 20 to detach from the bottom cover 30.

When connecting the upper cover 20 to the bottom cover 30, the hooks 42 are attracted by the magnet 60 to move away from its original position, which compresses the elastic members 53 as the elastic members 53 are blocked by the U-shaped blocks 22. The upper cover 20 can then be placed on the bottom cover 30 with proper orientation. The magnet 60 is then moved away from the upper cover 20 to allow the hooks 42 to move into its original position by the recovery of the elastic member 53. The hooks 42 are thus received in the notches 31 and connects the upper cover 20 to the bottom cover 30.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An electronic device comprising:
an upper cover;
a bottom cover;
a locking mechanism to connect the upper cover to the bottom cover, the locking mechanism comprising a plurality of protrusions formed on an inner surface of the bottom cover, a plurality of elastic members, and a blade slidably mounted on the upper cover and capable of being attracted by an external magnetic member, the blade formed with hooks, each protrusion defining a notch;
wherein the hooks are urged by the elastic members to be received in the notches and connect the upper cover to the bottom cover, the hooks are capable of moving out of the notches by the force of the external magnetic member, allowing the upper cover to detach from the bottom cover.

2. The electronic device of claim 1, wherein the locking mechanism further comprises a magnetic member fixed on the blade, the magnetic member is capable of attracted by the external magnetic member.

3. The electronic device of claim 1, wherein the blade defines a plurality of slide slots, the electronic device further comprises a plurality of bolts, the blots pass through the slide slots correspondingly to mount the blade on the upper cover, the blade is capable of moving along an extending direction of the slide slots.

4. The electronic device of claim 1, wherein the upper cover defines a plurality of U-shaped blocks, the blade is formed with a plurality of spindles, each of the elastic members is sleeved on a corresponding one of the spindles, a free end of each of the elastic members is blocked by the corresponding U-shaped block.

5. The electronic device of claim 1, wherein the upper cover is formed with restriction blocks, the blade is positioned below the restriction blocks.

6. A locking mechanism configured for connecting an upper cover to a bottom cover comprising:
a plurality of protrusions formed on an inner surface of the bottom cover, each protrusion defining a notch;
a plurality of elastic members; and
a blade slidably mounted on the upper cover and capable of being attracted by an external magnetic member, the blade formed with hooks;
wherein the hooks are urged by the elastic members to be received in the notches and connects the upper cover to the bottom cover, the hooks are capable of moving out of the notches by the force of the external magnetic member, allowing the upper cover to detach from the bottom cover.

7. The locking mechanism of claim 6, further comprises a magnetic member fixed on the blade, the magnetic member is capable of attracted by the external magnetic member.

8. The locking mechanism of claim 6, further comprises a plurality of bolts, the blade defines a plurality of slide slots, the blots passes through the slide slot correspondingly to mount the blade on the upper cover, the blade is capable of moving along an extending direction of the slide slots.

9. The locking mechanism of claim 6, wherein the blade is formed with a plurality of spindles, each of the elastic members is sleeved on the corresponding one of the spindles, free ends of the elastic members are correspondingly blocked by a plurality of U-shaped blocks defined on the upper cover.
